(19) United States
(12) Patent Application Publication
(10) Pub. No.: US 2018/0047879 A1
(43) Pub. Date: Feb. 15, 2018

(54) METHOD FOR PRODUCING A MULTIPLICITY OF CONVERSION ELEMENTS, CONVERSION ELEMENT, AND OPTOELECTRONIC DEVICE

(71) Applicant: OSRAM Opto Semiconductors GmbH, Regensburg (DE)

(72) Inventors: David RACZ, Regensburg (DE); Matthias SPERL, Mintraching (DE); Luca HAIBERGER, Regensburg (DE)

(21) Appl. No.: 15/555,483

(22) PCT Filed: Mar. 7, 2016
(86) PCT No.: PCT/EP2016/054801

§ 371 Date: Sep. 1, 2017

(30) Foreign Application Priority Data
Mar. 11, 2015 (DE) 10 2015 103 571.5

(51) Int. Cl. H01L 33/50

(52) U.S. Cl. CPC H01L 33/505; H01L 2933/0041; H01L 2224/48091; H01L 2224/48247; H01L 2224/48472; H01L 24/48

(57) ABSTRACT

The invention relates to a method for producing a plurality of conversion elements (6) comprising the following steps: providing a substrate (1); applying a first mask layer (4) to the substrate (1), the first mask layer (4) being structured with through-holes (3) which completely penetrate the first mask layer (4); applying a conversion material (5) at least into the through-holes (3); and singulating the conversion elements (6) so as to produce a plurality of individual conversion elements (6). The invention also relates to two other methods, to a conversion element (6), and to an optoelectronic component.

Three methods for producing a multiplicity of conversion elements, a conversion element and an optoelectronic device and a method for producing an optoelectronic device are provided.

This patent application claims priority from German patent application DE 10 2015 103 571.5, whose disclosure content is hereby included by reference.

Methods for producing conversion elements are described for example in documents DE 10 2007 043183 A1, DE 10 2013 103983 A1 and US 2012/0273807 A1.

It is an object of the present application to provide methods for producing a multiplicity of conversion elements with which conversion elements may be obtained, the shape of which is particularly well defined. It is further intended to provide a conversion element of particularly well defined shape and an optoelectronic device with such a conversion element.

These objects are achieved respectively by a method having the steps of claim 1, of claim 7 and of claim 13, by a conversion element having the features of claim 16 and by an optoelectronic device having the features of claim 17.

Advantageous further developments and embodiments of the methods, of the conversion element and of the optoelectronic device constitute the subject matter of the respective dependent claims.

The conversion element produced using the methods described here is of wavelength-converting configuration. The term “wavelength conversion” is here understood in particular to mean the conversion of irradiated electromagnetic radiation of one particular wavelength range into electromagnetic radiation of another, preferably longer-wave, wavelength range. In particular, during wavelength conversion electromagnetic radiation of one irradiated wavelength range is absorbed by the wavelength-converting element, converted by electronic processes at an atomic and/or molecular level into electromagnetic radiation of another wavelength range and re-emitted. In particular, the term “wavelength conversion” does not in the present case mean merely scattering or merely absorption of electromagnetic radiation.

In a method for producing a multiplicity of conversion elements, first of all a carrier is provided. The carrier is particularly preferably at least transparent to visible light. The carrier for example comprises one of the following materials or is formed from one of the following materials: sapphire, glass, borosilicate glass.

According to one embodiment of the method, a first mask layer patterned with openings is applied to the carrier. In the region of the openings the carrier is freely accessible.

According to one embodiment of the method, a sacrificial layer is applied to the carrier. In this case, the sacrificial layer is freely accessible through the openings.

According to a further embodiment of the method, a conversion material is introduced at least into the openings. The conversion material is in this respect generally present in flowable form. In this case, the conversion material is generally cured at a later point of the method.

According to a further embodiment of the method, the conversion elements are singulated, such that a multiplicity of individual conversion elements are produced. The conversion elements may in this case be fixed to a film prior to singulation, such that after singulation they are present on the film as finished conversion elements and may be simply further processed, for example by a pick-and-place process.

Within the openings, the conversion material preferably in each case laterally directly adjoins the first mask layer. Furthermore, within the openings the conversion material preferably in each case terminates flush with a surface of the first mask layer. In other words, the conversion material preferably completely fills the openings.

The openings in the first mask layer preferably form inverse shapes for the conversion material and predetermine the subsequent shape of the conversion elements or at least of the wavelength-converting element of the conversion element.

The idea underlying the production methods described here for the conversion elements is to reproduce mask layer patterns with the conversion material and so to arrive at a conversion element with a well-defined shape. In particular, the conversion element produced using the methods described here as a rule has a very smooth major face and smooth side faces for instance compared with a resin-based, for instance silicone-based, conversion plate produced by screen printing. Slumping over the entire area, as observed in the case of printed conversion elements, is also not generally displayed by the conversion elements produced using the methods described here. Furthermore, comparatively thick conversion elements and conversion elements with a small edge length may advantageously be produced using the methods described here.

The conversion elements described here are preferably resin-based, for example silicone-based. Resin-based conversion elements have the advantage over ceramic conversion elements of being capable in a simple manner of containing a plurality of different luminescent materials.

In particular, if the carrier is no longer part of the subsequent conversion element, a very wide variety of shapes is possible for the subsequent conversion element. The subsequent conversion element particularly preferably comprises a cutout for a subsequent bonding wire. Such a cutout for a bonding wire is preferably arranged at the edge of the conversion element. A bonding wire cutout may be shaped particularly precisely with the methods provided here.

According to a further embodiment of the method, singulation of the conversion elements proceeds by sawing, punching or laser writing and breaking, wherein the carrier is likewise diced, such that the carrier is in each case part of the subsequent conversion elements. In this case, the carrier preferably serves in mechanical stabilization of the conversion element. Consequently, the conversion material may advantageously be shaped in such a way that alone it is not mechanically stable. Such conversion elements are less expensive than ceramic conversion elements. In this embodiment, the conversion elements generally have rectangular shapes.

According to a further embodiment of the method, the first mask layer is likewise diced, such that side faces of the conversion material are covered with a layer of the first mask layer. In this embodiment the first mask layer advantageously does not have to be removed. This simplifies the method. Furthermore, the mask layer may be configured to absorb or indeed reflect incident and/or converted light. Such a layer on the side faces of the finished conversion element subsequently prevents output of light via the side faces of the conversion element and thus prevents optical crosstalk.

According to a further embodiment of the method, prior to application of the conversion material a reflective layer is applied to the first mask layer which covers the side faces of the conversion material after singulation. Particularly preferably, the reflective layer completely covers the side faces of the conversion material. The reflective layer on the side faces is preferably configured to be reflective for incident and/or converted light. The reflective layer on the side faces of the finished conversion element likewise subsequently prevents output of light via the side faces of the conversion element and thus prevents optical crosstalk. Furthermore, the reflective layer may also render the color appearance of the emitted light uniform whatever the viewing angle.

The reflective layer preferably comprises one of the following metallic materials or is formed from one of the following materials: silver, gold, aluminum, platinum. Furthermore, the reflective layer may also be configured as a dielectric mirror, which for example comprises layers of silver and silicon oxide.

The reflective layer preferably has a thickness of between 0.1 micrometers and 200 micrometers inclusive.

To produce a reflective layer on the side faces of the conversion material, a second patterned mask layer may for example be applied to the carrier. The second mask layer preferably comprises pattern elements or is formed from pattern elements which are arranged in the openings in the first mask layer.

According to one embodiment, to this end a metallic seed layer is applied to the first mask layer and the second mask layer, preferably over the entire surface thereof. Particularly preferably, side walls of the first mask layer are here covered with the metallic seed layer. Deposition may for example proceed by means of one of the following methods: sputtering, PVD, evaporation.

The metallic seed layer for example comprises one of the following materials or is formed from one of the following materials: chromium, titanium, platinum, aluminum, copper, silver.

The seed layer preferably has a thickness of between 0.05 micrometers and 0.2 micrometers inclusive.

After deposition of the metallic seed layer, the second mask layer is removed again, such that only the first mask layer is covered with the metallic seed layer. The carrier or the sacrificial layer is preferably exposed in the region of the openings. The seed layer is then molded over, such that the reflective layer arises on the first mask layer. Molding over of the seed layer may be carried out for example using a galvanic process. The galvanic process may proceed with or without electric current.

The first mask layer, on which the reflective layer has been deposited, is then present on the carrier. The openings in the first mask layer are then, as already described, filled with the conversion material and the conversion elements are finished.

As an alternative to the method just described for producing the reflective layer on the side faces of the conversion elements, the reflective layer may also be applied to the first mask layer and the second mask layer without prior application of a seed layer. Preferably, the reflective layer is applied over the entire surface. However, sputtering is preferably used here and not a galvanic process.

After deposition of the reflective layer the second mask layer is removed again, such that only the first mask layer is covered with the reflective layer and the carrier is exposed in the regions of the openings. Then the conversion elements may again be further processed, beginning with application of the conversion material.

If one of the described embodiments of the method is used to apply a reflective layer to the side faces of the conversion material, it is also possible for the first mask layer again likewise to be diced on singulation of the conversion elements, such that the reflective layer is covered with a layer of the first mask layer.

According to one further method for producing a multiplicity of conversion elements, a first mask layer is provided, the pattern elements of which have an undercut. Such pattern elements may for example be achieved with a two-layer system of different photoresist layers.

A metallic seed layer is applied between the pattern elements and the first mask layer is removed again, such that the seed layer is only formed between the pattern elements. The pattern elements with the undercut here serve as a shadow mask for the seed layer. Finally, a reflective layer is applied to the pattern elements of the seed layer, which reflective layer is provided to cover the side faces of the conversion material of the finished conversion elements.

In this method, the seed layer forms, with the reflective layer, the shapes which are to be reproduced by the conversion material, wherein the seed layer and the reflective layer are subsequently, as coating for the side faces of the conversion material, at least in part a component part of the conversion elements. Particularly preferably, the seed layer, together with the reflective layer, has a height which is greater than the subsequent thickness of the conversion elements. For example, the height of the seed layer together with the reflective layer is at least 50 micrometers.

The first mask layer and the second mask layer may be formed from a photoresist. A photoresist is preferably used here from which patterns with a comparatively high aspect ratio may be produced. With these photoresists it is in particular possible to achieve conversion elements of great thickness.

The photoresist of the second mask layer is preferably easily chemically soluble compared with the photoresist of the first mask layer. A dry resist may for example be used for the second mask layer, which dry resist is deep-drawn in order better to reproduce the topography of the first mask layer. After exposure and development of the photoresist of the second mask layer, said photoresist then preferably only remains where no first mask layer is located.

In the methods described here the conversion material may for example be applied using one of the following methods: doctor blading, spray coating, dispensing, printing, press-forming. Suitable printing methods are for example screen printing or stencil printing.

If the conversion material is press-formed, channels are preferably provided in the directly adjoining material, i.e. the carrier, the sacrificial layer or the mask layer, which channels extend away from the shapes for the conversion elements. These channels serve to remove air from the shapes during the forming process.

The conversion material preferably comprises a resin, for instance silicone, into which luminescent material particles have been introduced. Such conversion elements are also known as “resin-based”. The luminescent material particles give the conversion material and thus the conversion element their wavelength-converting characteristics. The resin is generally initially present in liquid form and is cured after application.

The resin may for example comprise an epoxide or a silicone or a mixture of these materials.

One of the following materials is for example suitable for the luminescent material particles: rare earth metal-doped garnets, rare earth metal-doped alkaline earth sulfides, rare earth metal-doped thiogallates, rare earth metal-doped aluminates, rare earth metal-doped silicates, rare earth metal-doped orthosilicates, rare earth metal-doped chlorosilicates, rare earth metal-doped alkaline earth silicon nitrides, rare earth metal-doped oxynitrides, rare earth metal-doped aluminum oxynitrides, rare earth metal-doped silicon nitrides, rare earth metal-doped sialons, quantum dots.

In the methods described here, the conversion elements may be applied to a film by their major face remote from the carrier and the carrier may be removed again, such that the multiplicity of conversion elements are present on the film. The carrier may for example be removed using a laser lift-off process.

In the methods described here, a sacrificial layer may be arranged between the carrier and the first mask layer. The sacrificial layer is provided for removing the carrier from the conversion elements through removal of the sacrificial layer. Removal of the sacrificial layer may proceed for example by means of a wet chemical process or a laser lift-off process.

The sacrificial layer may for example comprise one of the following materials or be formed from one of the following materials: molybdenum, silicon nitride, silicon oxide.

The sacrificial layer may for example be deposited using one of the following methods: evaporation, PVD, sputtering.

The sacrificial layer preferably has a thickness of between 10 nanometers and 200 nanometers inclusive.

According to one embodiment of the methods, patterns are applied in the carrier which are intended to be reproduced in the subsequently applied conversion material. The patterns may for example be lenses, microlenses or Fresnel patterns. Such patterns may, if the carrier is removed again from the conversion material, be reproduced in a radiation exit surface of the conversion element. In this respect, as a rule only comparatively coarse patterns are possible, for example lenses. If the carrier remains in the finished conversion elements, it is also possible to reproduce fine patterns from the carrier, such as for example microlenses or Fresnel patterns, in the conversion material. If the carrier is of glass, the patterns may for example be etched into the glass. The patterns serve to influence radiation outcoupling in a desired manner. For instance, the patterns may be suitable for rendering the color of the emitted light uniform as a function of the viewing angle or for achieving directional emission.

In a further method for producing a multiplicity of conversion elements, a carrier is again provided. The carrier comprises a multiplicity of recesses. The recesses are preferably all of identical configuration. The recesses are for example of lenticular configuration. If the carrier is formed from glass, hemispherical recesses may be formed in the carrier by isotropic etching, for example with hydrofluoric acid. Cuboidal recesses may for example be formed by means of anisotropic dry etching processes.

A conversion material is then introduced into the recesses. The conversion material preferably fills the recesses in each case completely. For example, the conversion material fills the recesses such that the conversion material forms a plane surface with the carrier. For introduction of the conversion material into the recesses, a mask may likewise be used which preferably prevents conversion material from being applied to the carrier between the recesses.

Finally, the conversion elements are singulated, for example by means of scribing and/or breaking. One conversion element then comprises one part of the carrier with at least one recess, which is filled with the conversion material.

According to one embodiment of the method, on singulation of the conversion elements the carrier is likewise diced, such that the carrier is in each case part of the finished conversion element.

According to one further embodiment of the method, a sacrificial layer is applied to the carrier, such that at least the recesses are provided with the sacrificial layer. The conversion material is then applied to the sacrificial layer. Finally, the assembly of conversion material and carrier is fixed to a film. Fixing of the film preferably proceeds such that the recesses with the conversion material point towards the film. The film may for example be a thermorelease film or a UV release film. Finally the carrier is removed. The carrier is preferably removed by removing the sacrificial layer.

The conversion elements obtained with the present methods preferably have a thickness of at least 50 micrometers. The thickness of the conversion elements preferably merely deviates by at most 10% from a mean over one of the major faces thereof.

Compared with screen or stencil printing without a mask layer, high thickness conversion elements with a precise surface finish may be produced using the methods described here. High thickness conversion elements are suitable in particular for lateral encapsulation with a reflective potting compound, as is advantageous for the production of point light sources.

The conversion element produced using the methods described here is suitable in particular for use in an optoelectronic device. The conversion element is for example part of a light-emitting diode.

The optoelectronic device preferably comprises at least one radiation-emitting semiconductor chip, which emits electromagnetic radiation of a first wavelength range. The semiconductor chip for example emits blue light. The conversion element is arranged in such a way within the optoelectronic device that radiation of the semiconductor chip passes through the conversion element.

The conversion element is suitable for converting at least one part of the radiation of the semiconductor chip into radiation of at least one other wavelength range. The conversion element for example converts one part of the blue radiation of the semiconductor chip into yellow light, such that the semiconductor device emits polychromatic white light from unconverted blue radiation and converted yellow radiation.

The conversion element is preferably arranged downstream of the semiconductor chip in the main emission direction thereof. The conversion element is particularly preferably arranged on a radiation exit surface of the semiconductor chip.

Due to its particularly well defined shape, the present conversion element is suitable in particular for use in an electronic device which is intended to serve as a point light source. Such an optoelectronic device preferably comprises a white, diffusely reflective potting material which at least encapsulates side faces of the semiconductor chip.

Features and embodiments which are here described only in conjunction with a method, the conversion element or the device may likewise be embodied in the other methods, the conversion element or the device.

Further advantageous embodiments and further developments of the invention are revealed by the exemplary embodiments described below in connection with the figures.

One exemplary embodiment of a method for producing a conversion element is explained in greater detail with reference to the schematic sectional representations of FIGS. 1 to 8.

The schematic plan view of FIG. 9 shows conversion elements according to various exemplary embodiments.

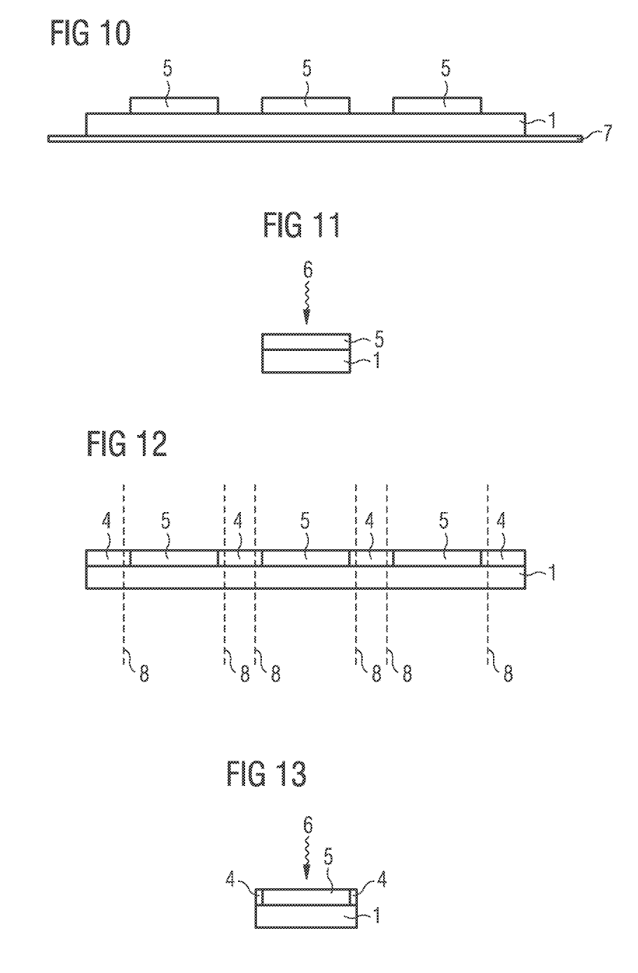

A further exemplary embodiment of a method for producing a conversion element is explained in each case with reference to the schematic sectional representations of FIGS. 10 and 12.

The schematic sectional representations of FIGS. 11 and 13 show a conversion element in each case according to one exemplary embodiment.

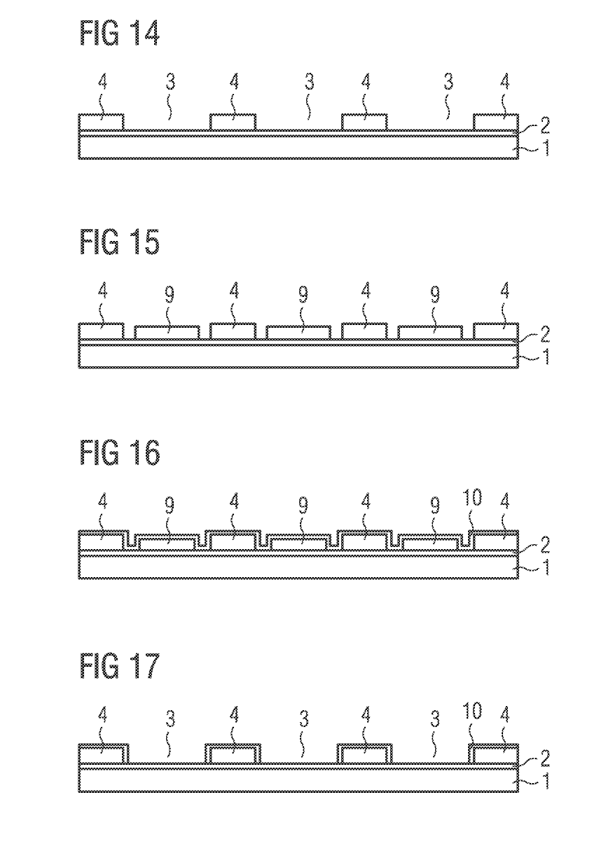

A further exemplary embodiment of a method for producing a conversion element is explained in greater detail with reference to the schematic sectional representations of FIGS. 14 to 20.

The schematic sectional representation of FIG. 21 shows a conversion element according to a further exemplary embodiment.

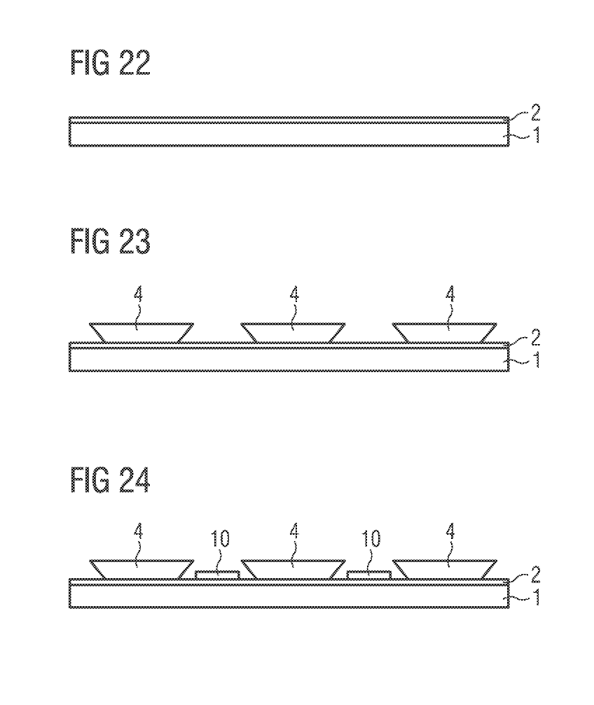

A further exemplary embodiment of a method for producing a conversion element is explained in greater detail with reference to the schematic sectional representations of FIGS. 22 to 29.

The schematic sectional representation of FIG. 30 shows a conversion element according to a further exemplary embodiment.

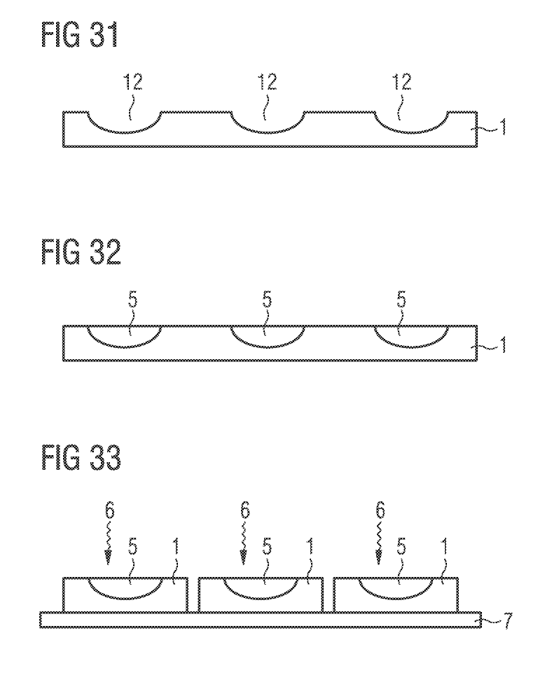

A further exemplary embodiment of a method for producing a conversion element is explained in greater detail with reference to the schematic sectional representations of FIGS. 31 to 33.

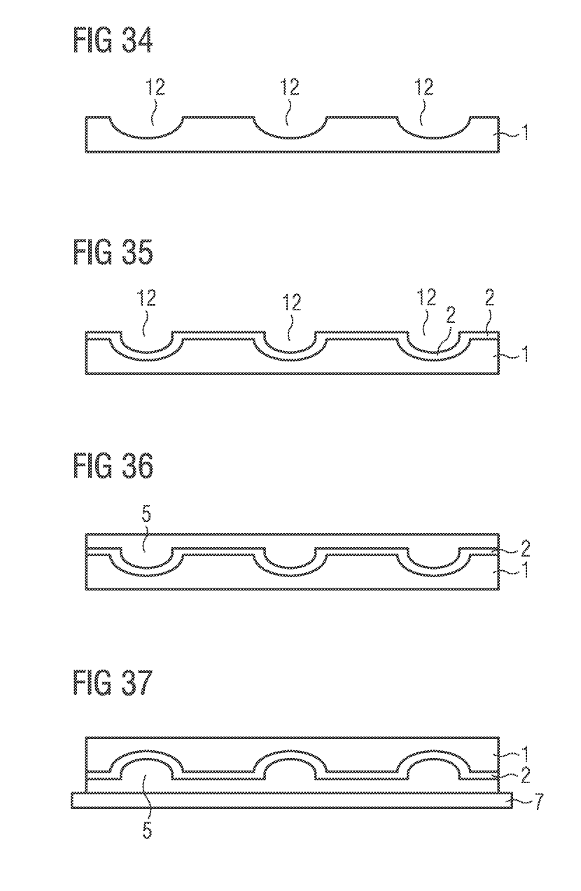

A further exemplary embodiment of a method for producing a conversion element is explained in greater detail with reference to the schematic sectional representations of FIGS. 34 to 38.

One exemplary embodiment of a method for producing an optoelectronic device is explained in greater detail with reference to the schematic sectional representations of FIGS. 39 to 41.

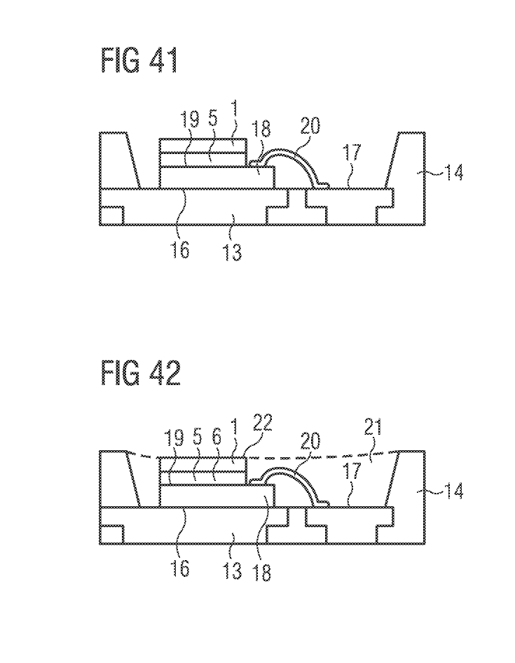

FIG. 42 is a schematic sectional representation of an optoelectronic device according to one exemplary embodiment.

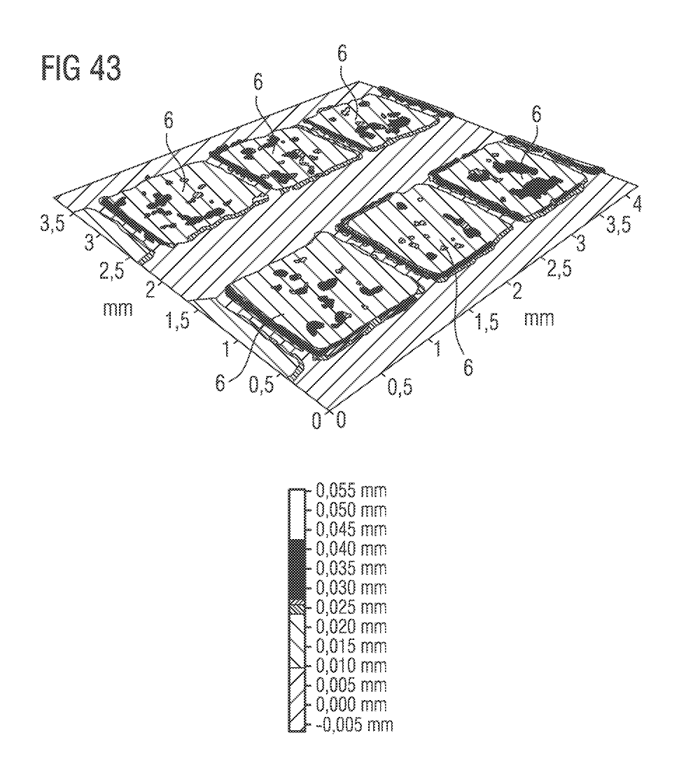

FIG. 43 shows an example of a 3D measurement of the height profile of a plurality of conversion elements.

Identical, similar or identically acting elements are provided with the same reference numerals in the figures. The figures and the size ratios of the elements illustrated in the figures relative to one another are not to be regarded as being to scale. Rather, individual elements, in particular layer thicknesses, may be illustrated on an exaggeratedly large scale for greater ease of depiction and/or better comprehension.

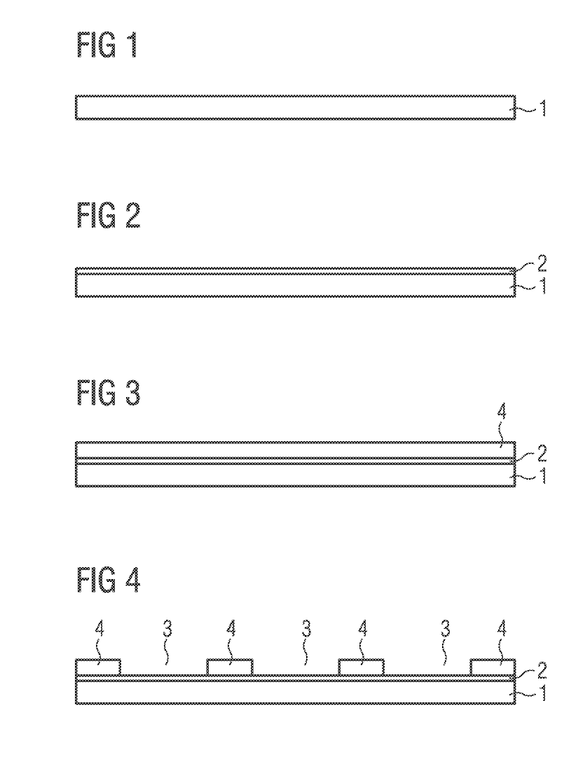

With the method according to the exemplary embodiment of FIGS. 1 to 8, in a first step a carrier 1 is provided (FIG. 1). A sacrificial layer 2 is applied to the carrier 1 (FIG. 2) over the entire surface thereof, and a photoresist layer is deposited thereon again over the entire surface (FIG. 3).

The photoresist layer is then patterned in such a way by exposure and development that openings 3 arise in the photoresist layer (FIG. 4). In the present case, the openings 3 pass right through the photoresist layer, such that the sacrificial layer 2 is freely accessible from outside in the region of the openings 3. In the method according to FIGS. 1 to 8 the photoresist layer serves as a first mask layer 4.

In a next step the openings 3 in the first mask layer 4 are completely filled with a conversion material 5 (FIG. 5). The conversion material 5 is here formed from a silicone, into which luminescent material particles have been introduced. The luminescent material particles give the finished conversion element its wavelength-converting characteristics.

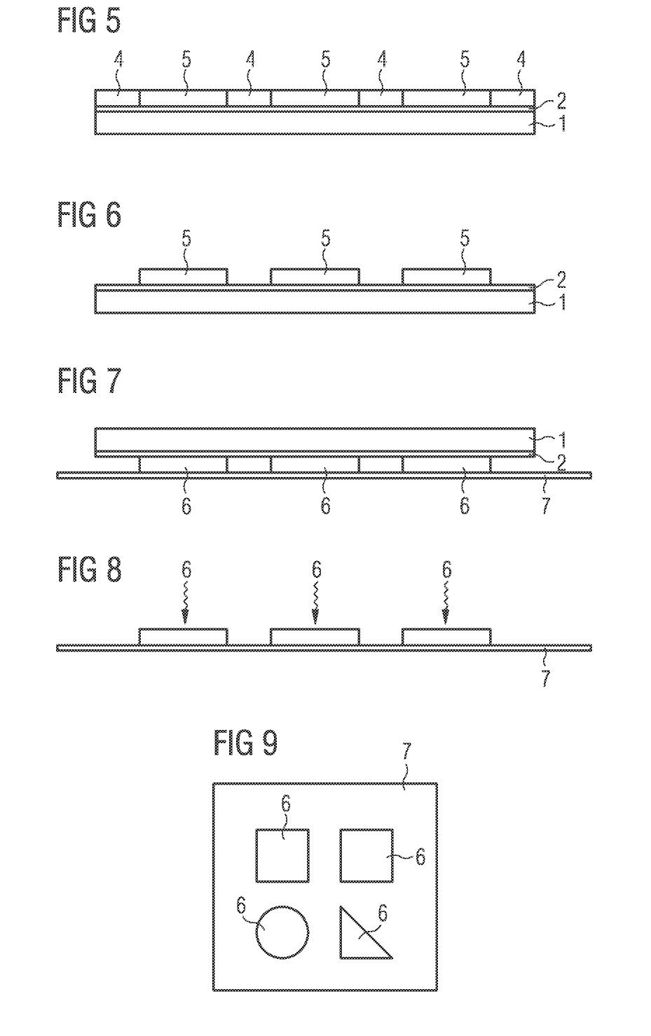

The silicone is then cured and the first mask layer 4 is removed again (FIG. 6).

The conversion elements 6 are applied by just their exposed major face to a film 7 (FIG. 7) and the carrier 1 is removed again. In the present case, the carrier 1 is removed by removal of the sacrificial layer 2. Individual conversion elements 6 are now present on the film (FIG. 8). The finished conversion elements 6 may be removed from the film 7 for example by pick-and-place and further processed.

The plan view of FIG. 9 shows a schematic plan view onto a film 7 with a plurality of different conversion elements 6 according to various embodiments. The conversion elements 6 here have various geometric shapes, by way of example. The illustration is here intended to demonstrate that different geometric shapes are possible using the method presented. As a rule, the conversion elements 6 which are present on a film 7 once the method has been carried out in reality have the same geometric shape.

The geometric shape of the conversion elements 6 is here determined by the geometric shape of the openings 3 which are introduced into the first mask layer 4. For example, the conversion elements 6 may have a rectangular shape, a round or indeed a triangular shape.

In the method according to the exemplary embodiment of FIG. 10, first of all the steps are carried out as already described with reference to FIGS. 1 to 6, wherein however application of the sacrificial layer 2 to the carrier 1 is omitted. Once these steps have been carried out, individual cured regions with conversion material 6 are present on the carrier 1. This assembly is then applied by the major face of the carrier 1, which is remote from the conversion material 5, to a film 7 (FIG. 10). The conversion elements 6 are then singulated, for example by sawing. Unlike in the method according to FIGS. 1 to 9, the carrier 1 remains a component part of the finished conversion elements 6.

A conversion element 6 such as may be produced with the method according to FIG. 10 is shown schematically in FIG. 11. The conversion element 6 is formed from the carrier 1 and the cured conversion material 5, wherein the cured conversion material 5 is applied in direct contact to the carrier 1. The conversion material 5 gives the conversion element 6 its wavelength-converting characteristics.

In the method according to the exemplary embodiment of FIG. 12, firstly the method steps are likewise carried out as already described with reference to FIGS. 1 to 6, wherein again application of the sacrificial layer 2 is omitted (FIG. 12). In a next step the conversion elements 6 are then singulated, for example by sawing or writing and breaking. In this case, dicing lines 8, along which dicing is to be performed, extend within the first mask layer 4, such that side faces of the conversion material 5 are covered with material of the first mask layer 4 (FIG. 13).

A conversion element 6 such as may be produced with the method according to FIG. 12 is shown schematically in FIG. 13. The conversion material 5 of the conversion element 6 according to the exemplary embodiment of FIG. 13 has been applied to the carrier 1 and provided laterally all over with the material of the first mask layer 4.

In the method according to the exemplary embodiment of FIGS. 14 to 20, a first patterned mask layer 4 is applied to a carrier 1 provided with a sacrificial layer 2, as has already been described in detail with reference to FIGS. 1 to 4 (FIG. 14).

In a next step pattern elements 9 of a second mask layer are applied into the openings 3 in the first mask layer 4 (FIG. 15). One pattern element 9 of the second mask layer is here arranged in each opening 3. Like the first mask layer, the second mask layer may be formed from a photoresist.

Then a metallic seed layer 10 is applied by sputtering to the entire surface of the first mask layer 4 and the second mask layer (FIG. 16) and the second mask layer is removed again, for example with a solvent, such as acetone.

The sacrificial layer 2 now has the first mask layer 4 applied to it, which is completely covered with the metallic seed layer 10. In particular, side faces of the first mask layer 4 which delimit the openings 3 are completely covered with the seed layer 10 (FIG. 17).

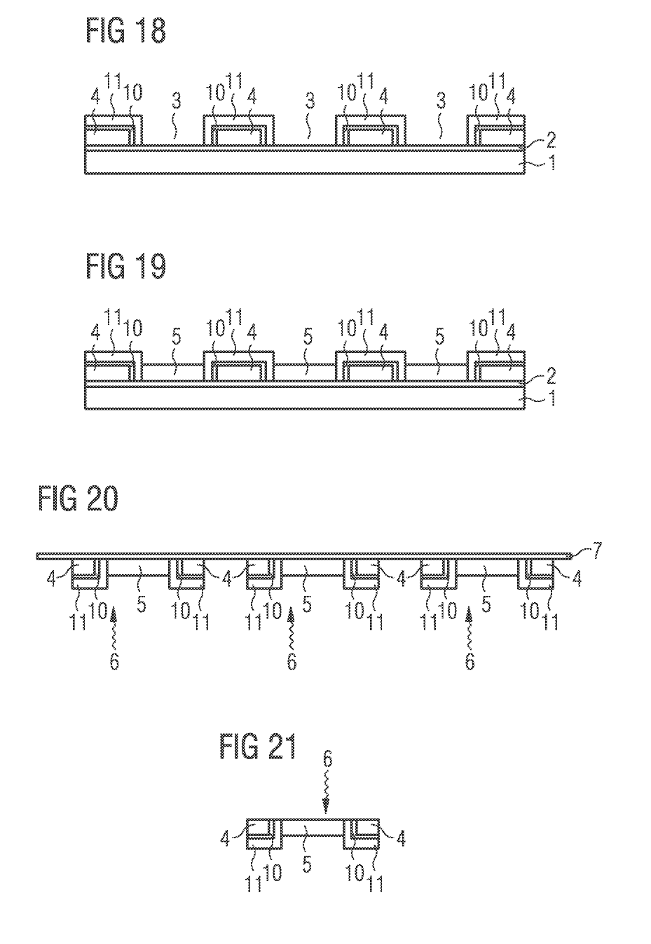

In a next step, the seed layer 10 is molded over with a further reflective layer 11 using a galvanic process (FIG. 18). The first mask layer 4 made thicker by the galvanically deposited reflective layer 11 is now taller than the subsequently applied conversion material 5.

In a next step, a conversion material 5 is introduced into the openings 3 in the galvanically thickened first mask layer 4 and cured. The assembly comprising the carrier 1 and the conversion material 5 is applied to a film 7, the carrier 1 is removed by removal of the sacrificial layer 2, and the conversion elements 6 are applied to a further film 7 and singulated (FIG. 20). The conversion elements 6 are singulated in such a way that the side faces of the conversion material 5 are provided with material of the galvanically deposited reflective layer 11.

As an alternative to the method in which first of all a seed layer 10 is applied by sputtering, which is then made thicker with a reflective layer 11 by a subsequent galvanic process, as described with reference to FIGS. 14 to 20, it is also possible for one thick reflective layer 11 to be deposited, for example by sputtering, uniformly on the first mask layer 4 and the second mask layer. This variant is not described in any more detail, to avoid repetition. A conversion element 6 is here also produced, as described with reference to FIG. 21.

A conversion element 6 such as may be produced with the method according to the exemplary embodiment of FIGS. 14 to 20 is illustrated schematically in FIG. 21. The conversion element 6 according to the exemplary embodiment of FIG. 21 comprises a layer of a conversion material 5 with side faces, which are provided all over with a reflective layer 11. Recesses are formed within the reflective layer 11, which recesses are filled with the material of the first mask layer 4, such as a photoresist (FIG. 21). The recesses with the photoresist here extend from a major face of the conversion element 6 over the side faces thereof. The reflective layer 11 on the side faces of the conversion material 5 here projects beyond a major face of the layer formed by the conversion material 5.

In the method according to the exemplary embodiment of FIGS. 22 to 29, first of all a sacrificial layer 2 is applied to a carrier 1 (FIG. 22). Then a first mask layer 4 with pattern elements is applied, said elements having an undercut (FIG. 23). As a result of the undercut, the side faces of the pattern elements each taper continuously towards the carrier 1. The cross-sectional area of the pattern elements decreases continuously from a major face remote from the carrier 1 to a major face facing the carrier 1.

In a next step, a metallic seed layer 10 is formed between the pattern elements of the first mask layer 4. The metallic seed layer 10 is applied by sputtering, for example, wherein the first mask layer 4 serves as a shadow mask.

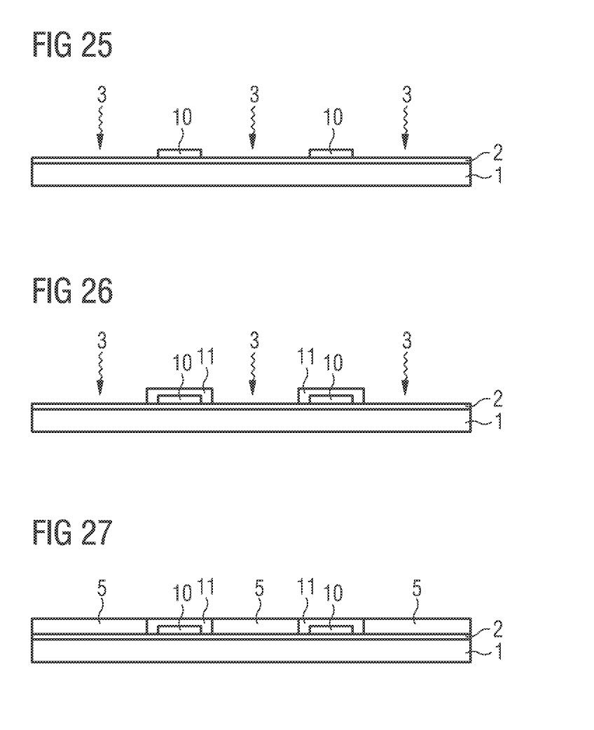

The first mask layer 4 is then removed again. The seed layer 10 then forms a pattern comprising openings 3 which establish the subsequent shape of the conversion elements 6 (FIG. 25). Galvanic deposition is used to thicken the seed layer 10 with a further, reflective layer 11 (FIG. 26).

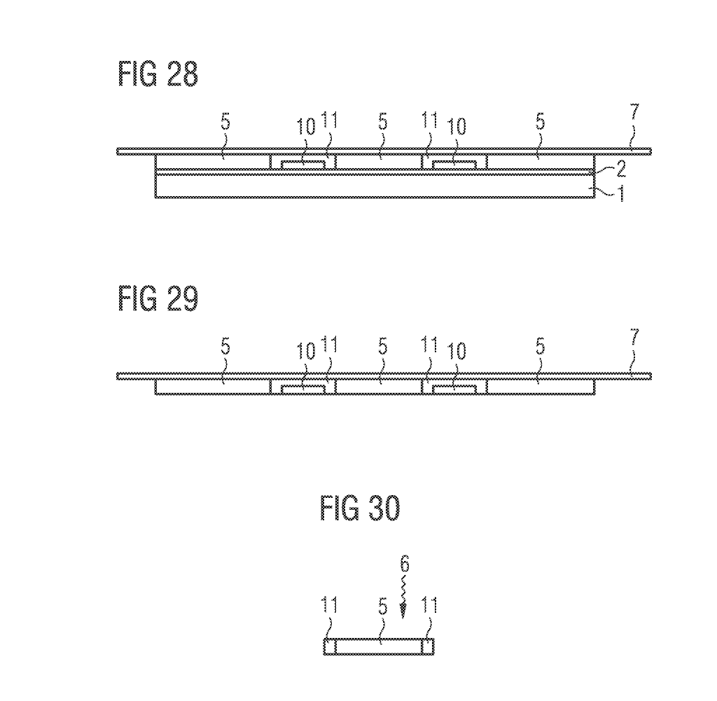

In a next step, the openings 3 in the seed layer 10 are completely filled with a conversion material 5 (FIG. 27) and the assembly of carrier 1 and conversion material 5 is applied to a film 7 (FIG. 28). Finally, the carrier 1 is removed, by removing the sacrificial layer 2 (FIG. 29).

FIG. 30 shows a schematic sectional representation of a conversion element 6 such as may be produced for example by the method according to FIGS. 22 to 29. The conversion element 6 according to the exemplary embodiment of FIG. 30 comprises a layer of cured conversion material 5. The side faces of the conversion material 5 are here covered with a metallic reflective layer 11, which is formed from the material of the galvanically deposited metallic reflective reinforcing layer.

In the method according to the exemplary embodiment of FIGS. 31 to 33, first of all a carrier 1, for example of glass, is provided with a multiplicity of recesses 12 (FIG. 31). The recesses 12 are in the present case formed hemispherically in the carrier 1 by isotropic wet chemical etching.

In a next step, the recesses 12 are completely filled with a conversion material 5 (FIG. 32). The assembly of carrier 1 and conversion material 5 is then applied to a film 7 and singulated into individual conversion elements 6 for example by sawing (FIG. 33). A finished conversion element 6 is then formed of a carrier 1 which comprises a hemispherical recess 12 which is completely filled with a conversion material 5.

In the method according to the exemplary embodiment of FIGS. 34 to 38, a prepatterned glass carrier 1 such as already described with reference to FIG. 31 is likewise provided. A sacrificial layer 2, for example of silicon nitride, is then applied over the entire surface of the major face of the carrier 1 comprising the recesses 12 (FIG. 35).

In a next step, a conversion material 5 is applied to the sacrificial layer 2 by compression molding. The conversion material 5 is applied in such a way that not only are the recesses 12 in the carrier 1 completely filled with the conversion material 5 but also the conversion material 5 projects above the recesses 12 and forms a continuous layer on the carrier 1, which has to the greatest possible extent a uniform thickness over and between the recesses 12 (FIG. 36).

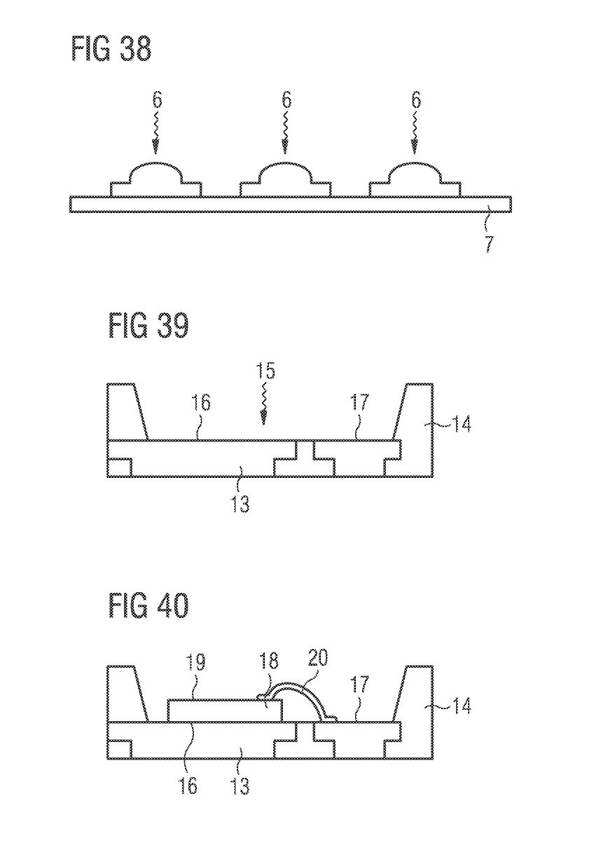

The assembly consisting of the conversion material 5 and the carrier 1 is then laminated onto a film 7 by its major face remote from the carrier 1 (FIG. 37). The carrier 1 is removed using a laser lift-off method, by removing the sacrificial layer 2 (FIG. 38). The conversion elements 6 are singulated. Each conversion element 6 comprises a conversion material 5 with a lenticular curvature, which is arranged on a layer-like part. The layer-like part of the conversion element 6 in each case projects laterally beyond the curved part.

In the method for producing an optoelectronic device according to FIGS. 39 to 42, firstly a device package is provided. The device package comprises a leadframe 13, which is embedded into a reflector 14 (FIG. 39). In a cavity 15 of the device package which is formed by the reflector 14, a first electrical connection point 16 and a second electrical connection point 17 of the leadframe 13 are exposed.

A radiation-emitting semiconductor chip 18, which emits blue light from a radiation exit surface 19 when in operation, is then mounted on the first electrical connection point 16 of the leadframe 14. The semiconductor chip 18 is connected electrically conductively with the second connection point 17 of the leadframe 13 by means of a bonding wire 20 (FIG. 40).

A conversion element 6, such as already described for example with reference to FIG. 11, is placed onto the radiation exit surface 19 of the semiconductor chip 18. The conversion element 6 here comprises a carrier 1 and a conversion material 5. The conversion element 6 is preferably arranged such that the conversion material 5 faces the radiation exit surface 19. The conversion material 5 is particularly preferably in direct contact with the radiation exit surface 19.

The cavity 15 of the device package is then filled with a reflective potting compound 21, which laterally encapsulates the semiconductor chip 18 and the conversion element 6 (FIG. 42). A radiation exit surface 22 of the conversion element 6 is here free of the reflective potting compound 21. In the present case, the reflective potting compound 21 is formed from a silicone into which titanium oxide particles have been introduced.

FIG. 43 shows by way of example a 3D measurement of height profiles of conversion elements 6 such as may be produced using the methods described here. The conversion elements 6 are of very even configuration. Even the edges of the conversion elements 6 are particularly uniformly reproduced.

The description made with reference to exemplary embodiments does not restrict the invention to these embodiments. Rather, the invention encompasses any novel feature and any combination of features, including in particular any combination of features in the claims, even if this feature or this combination is not itself explicitly indicated in the claims or exemplary embodiments.

1. Method for producing a multiplicity of conversion elements having the steps of:
providing a carrier,
applying a first mask layer to the carrier, wherein the first mask layer is patterned with openings which pass right through the first mask layer,
applying a conversion material at least into the openings, and
singulating the conversion elements, so as to result in a multiplicity of individual conversion elements in which, prior to application of the conversion material, a reflective layer is applied to the first mask layer which covers side faces of the conversion material after singulation.

2. Method according to claim 1,
in which the conversion elements are singulated by sawing or breaking, wherein the carrier is likewise diced, such that the carrier is in each case part of the subsequent conversion elements.

3. Method according to claim 1,
in which the first mask layer is likewise diced, such that the side faces of the conversion material are covered with a layer of the first mask layer.

4. Method according to claim 1,
in which
a second patterned mask layer is applied to the carrier, the pattern elements of which second mask layer are arranged in the openings in the first mask layer,
a metallic seed layer is applied over the entire surface of the first mask layer and the second mask layer,
the second mask layer is removed again, such that only the first mask layer is covered with the metallic seed layer and the carrier or the sacrificial layer is exposed in the region of the openings, and
the seed layer is galvanically molded over, such that the reflective layer arises on the first mask layer.

5. Method according to claim 1,
in which
a second patterned mask layer is applied to the carrier, the pattern elements of which second mask layer are arranged in the openings,
the reflective layer is applied over the entire surface of the first mask layer and the second mask layer, and
the second mask layer is removed again, such that only the first mask layer is covered with the reflective layer and the carrier or the sacrificial layer is exposed in the region of the openings.

6. Method according to claim 1,
in which, on singulation of the conversion elements, the first mask layer is likewise diced, such that the reflective layer is covered with a layer of the first mask layer.

7. Method for producing a multiplicity of conversion elements,
in which
a first mask layer is provided, the pattern elements of which have an undercut,
a metallic seed layer is applied to exposed regions between the pattern elements of the first mask layer,
the first mask layer is removed again, and
a reflective layer is applied to the pattern elements of the seed layer, which reflective layer is provided to cover the side faces of the conversion material of the finished conversion elements.

8. Method according to claim 1,
in which the first and/or the second mask layer is a photoresist layer.

9. Method according to claim 1,
in which the conversion material is applied using one of the following methods: doctor blading, spray coating, dispensing, printing, press-forming.

10. Method according to claim 1,
in which the conversion material comprises a resin with luminescent material particles.

11. Method according to claim 1,
in which the conversion elements are applied to a film by their major face remote from the carrier and the carrier is removed again, such that the multiplicity of conversion elements are present on the film.

12. Method according to claim 11,
in which a sacrificial layer is arranged between the carrier and the first mask layer and the carrier is removed by removal of the sacrificial layer from the conversion elements.

13. Method for producing a multiplicity of conversion elements, having the steps of:
providing a carrier which is patterned with a multiplicity of recesses, wherein the recesses have the shape of a lens,
introducing a conversion material into the recesses in the carrier, and
singulating the conversion elements.

14. Method according to claim 13,
in which, on singulation of the conversion elements, the carrier is likewise diced, such that the carrier is in each case part of the finished conversion element.

15. Method according to claim 13,
in which
a sacrificial layer is applied to the carrier, such that at least the recesses are provided with the sacrificial layer,
applying the assembly to a film, and
removing the carrier.

16. Conversion element produced using the method of claim 1.

17. Optoelectronic device with a conversion element according to claim 16.

18. Conversion element produced using the method of claim 7.

19. Conversion element produced using the method of claim 13.
